(19) United States
(12) Patent Application Publication
(10) Pub. No.: US 2010/0032659 A1
(43) Pub. Date: Feb. 11, 2010

(54) SEMICONDUCTOR DEVICE AND METHOD OF FABRICATING THE SAME

(75) Inventor: Takeshi YOSHIDA, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/506,650

(22) Filed: Jul. 21, 2009

(30) Foreign Application Priority Data
Aug. 5, 2008 (JP) 2008-201453

(51) Int. Cl. H01L 31/0248; H01L 31/0216; H01L 31/18

(52) U.S. Cl. 257/40; 257/436; 438/72; 257/461; 257/E31.119; 257/E31.002

(57) ABSTRACT

A semiconductor device 1 according to one embodiment of the invention includes: a semiconductor thin film having a light incident plane 30b on which a light is incident and a photodiode portion 30a; an interlayer 62 provided above a surface of the semiconductor thin film on an opposite side of the light incident plane 30b and having a convex surface 62a; and a concave reflective layer 70 having a concave surface 70a for reflecting the light toward the photodiode portion 30a.

### CROSS-REFERENCE TO RELATED APPLICATIONS

This application is based upon and claims the benefit of priority from prior Japanese Patent Application No. 2008-201453, filed on Aug. 5, 2008, the entire contents of which are incorporated herein by reference.

### BACKGROUND

As a conventional backside irradiation type semiconductor device with increased photosensitivity, a semiconductor device provided with a semiconductor layer having a light incident plane, a photoelectric conversion portion formed in the semiconductor layer and a reflective layer for reflecting a light transmitted through the photoelectric conversion portion toward the photoelectric conversion portion side on a surface opposite to the light incident plane, is known. This semiconductor device is disclosed in JP-A 2008-147333.

### BRIEF SUMMARY

One embodiment of the present invention provides a semiconductor device, comprising:

a semiconductor thin film comprising a light incident plane on which a light is incident and a photodiode portion;

an interlayer provided above a surface of the semiconductor thin film on an opposite side of the light incident plane, and having a convex surface; and a concave reflective layer provided on the surface of the convex surface, and having a concave surface for reflecting the light toward the photodiode portion.

In addition, another embodiment of the present invention provides a semiconductor device, comprising:

a transparent substrate having flexibility;

a transparent electrode provided on the transparent substrate;

an organic semiconductor layer provided on a portion of the transparent electrode on an opposite side of a surface thereof in contact with the transparent substrate;

an interlayer provided above a surface of the organic semiconductor layer on an opposite side of a surface thereof in contact with the transparent electrode, and having a convex surface; and

a concave reflective layer provided on the surface of the convex surface, and having a concave surface for reflecting an incident light toward the organic semiconductor layer.

In addition, still another embodiment of the present invention provides a semiconductor device, comprising:

a transparent substrate having flexibility, and being transparent to a visible light;

a transparent electrode provided on the transparent substrate;

an organic semiconductor layer provided on a portion of the transparent electrode on an opposite side of a surface thereof in contact with the transparent substrate; and

an reflective layer provided above a surface of the organic semiconductor layer on an opposite side of a surface thereof in contact with the transparent electrode.

In addition, still another embodiment of the present invention provides a method of fabricating a semiconductor device, comprising:

forming a film on a semiconductor thin film having an oxide film formed on a surface thereof, the semiconductor thin film comprising a light incident plane on which a light is incident and a photodiode portion;

processing the film into an interlayer having a convex shape by applying heat treatment to the film; and

forming a concave reflective layer on a surface of the interlayer.

### BRIEF DESCRIPTION OF THE DRAWINGS

FIG. 1 is a cross sectional view showing a semiconductor device according to a first embodiment;

FIG. 2A is a view showing a process for fabricating the semiconductor device according to the first embodiment;

FIG. 2B is a view showing a process for fabricating the semiconductor device according to the first embodiment;

FIG. 2C is a view showing a process for fabricating the semiconductor device according to the first embodiment;

FIG. 2D is a view showing a process for fabricating the semiconductor device according to the first embodiment;

FIG. 2E is a view showing a process for fabricating the semiconductor device according to the first embodiment;

FIG. 2F is a view showing a process for fabricating the semiconductor device according to the first embodiment;

FIG. 2G is a view showing a process for fabricating the semiconductor device according to the first embodiment;

FIG. 2H is a view showing a process for fabricating the semiconductor device according to the first embodiment;

FIG. 2I is a view showing a process for fabricating the semiconductor device according to the first embodiment;

FIG. 2J is a view showing a process for fabricating the semiconductor device according to the first embodiment;

FIG. 3 is a view showing an operation of the semiconductor device according to the first embodiment;

FIG. 4 is a view showing a position of a center of curvature of the semiconductor device according to the first embodiment;

FIG. 5 is a cross sectional view showing a semiconductor device according to a second embodiment; and

FIG. 6 is a cross sectional view showing a semiconductor device according to a third embodiment.

### DETAILED DESCRIPTION

### First Embodiment

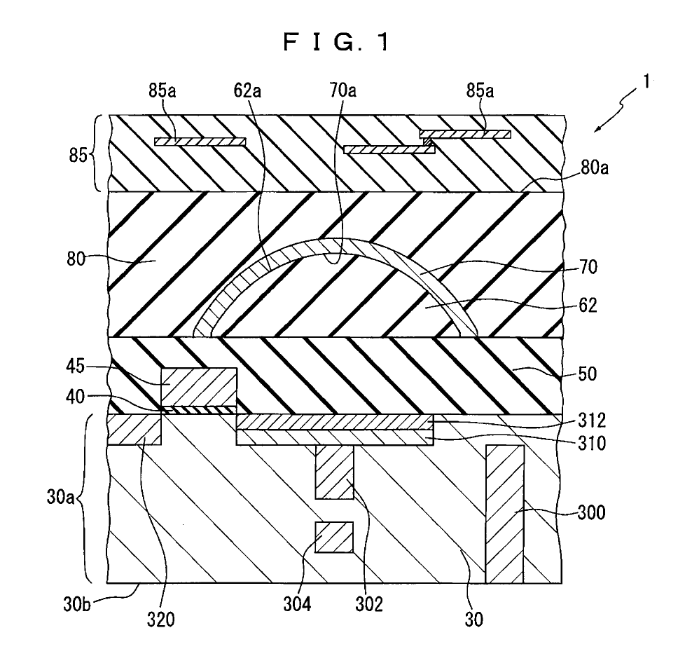

FIG. 1 is a cross section schematically showing a semiconductor device according to a first embodiment.

A semiconductor device 1 according to the first embodiment includes a p-type Si thin film 30 as a semiconductor thin film which has a photodiode portion 30a having a photoelectric conversion function and a light incident plane 30b, a gate oxide film 40 formed in a region which is a portion of the surface of the p-type Si thin film 30 on the opposite side of the light incident plane 30b, a gate electrode 45 formed on the gate oxide film 40, an oxide film 50 covering a surface of the p-type Si thin film 30 on the gate electrode 45 formed side and the gate oxide film 40 and the gate electrode 45, an interlayer 62 provided on a portion of the surface of the oxide film 50 on the opposite side of the p-type Si thin film 30, a concave reflective layer 70 covering a surface of the interlayer 62, an interlayer insulating film 80 provided so as to cover a surface of the concave reflective layer 70 and a surface of a portion of the oxide film 50, and a wiring layer 85 provided on a surface 80a of the interlayer insulating film 80 and having wirings 85a.

In addition, the p-type Si thin film 30 has an n⁺ layer 310 as a first layer, a p⁺ layer 312 as a second layer and a drain region 320. The n⁺ layer 310 and the p⁺ layer 312 are provided in the p-type Si thin film 30 in this order from the light incident plane 30b side toward another surface side of the p-type Si thin film 30. Thus, a portion immediately under the gate oxide film 40 is sandwiched by the n⁺ layer 310/the p⁺ layer 312 and the drain region 320. Furthermore, the p-type Si thin film 30 has an n⁺ region 302 provided in the p-type Si thin film 30 below the n⁺ layer 310, and a p⁺ region 304 provided in the p-type Si thin film 30 below the n⁺ region 302. The photodiode portion 30a is composed so as to include the n⁺ layer 310, the p⁺ layer 312, the drain region 320, the n⁺ region 302 and the p⁺ region 304. In addition, the p-type Si thin film 30 has an n-type partition wall 300 on a side of the n⁺ region 302 and the p⁺ region 304 opposite to the gate oxide film 40 for isolating plural photodiode portions 30a.

The semiconductor device 1 according to the present embodiment is, e.g., a backside irradiation type photosensor using the photodiode portion 30a having a function as a photodiode.

The p-type Si thin film 30 is made of, e.g., Si having a specific resistance of 1 Ω·cm, and being doped with a p-type impurity at a predetermined impurity concentration. The p-type Si thin film 30 is formed having, e.g., a thickness of about 1.5 μm. The n-type partition wall 300 is formed having a predetermined width and depth from the light incident plane 30b side of the p-type Si thin film 30 toward the surface of the p-type Si thin film 30 on the opposite side of the light incident plane 30b in order to electrically isolate the plural photodiode portions 30a. The n-type partition wall 300 is formed containing an n-type impurity at a predetermined impurity concentration, e.g., containing phosphorus (P), etc., at a predetermined impurity concentration.

In addition, the n⁺ region 302 as a first region contains an impurity of n-type as a first conductivity type at a concentration higher than a concentration of an impurity contained in the p-type Si thin film 30. Similarly, the p⁺ region 304 as a second region contains an impurity of p-type as a second conductivity type at a concentration higher than the concentration of the impurity contained in the p-type Si thin film 30. The n⁺ layer 310 is formed containing an n-type impurity, and the p⁺ layer 312 is formed containing a p-type impurity. Then, the n⁺ layer 310 together with the p⁺ layer 312 performs a function as an electrode of the photodiode portion 30a.

The gate electrode 45 is made of, e.g., polycrystalline silicon or polycrystalline silicon germanium containing an impurity of a predetermined conductivity type. For example, an n-type gate electrode 45 contains an n-type impurity such as arsenic (As) or P, etc., as an impurity. Meanwhile, a p-type gate electrode 45 contains a p-type impurity such as B or boron difluoride (BF₂), etc.

Alternatively, the gate electrode 45 may be formed of a metal gate electrode made of a metal material such as (W), tantalum (Ta), titanium (Ti), hafnium (Hf), zirconium (Zr), ruthenium (Ru), platinum (Pt), iridium (Ir), Mo or Al, etc., or a compound thereof, etc. The gate oxide film 40 is made of, e.g., an insulating material such as SiO₂, silicon nitride (SiN), SiON, or a high-dielectric material (e.g., an Hf-based material such as HfSiON, HfSiO or HfO, etc., a Zr-based material such as ZrSiON, ZrSiO or ZrO, etc., and a Y-based material such as Y₂O₃, etc.). In addition, the oxide film 50 and the interlayer insulating film 80 are made of, e.g., an insulating material such as SiO₂, etc., having a thermal expansion coefficient of 0.5 ppm/° C.

Meanwhile, the interlayer 62 is formed having a convex surface 62a being convex in a direction to separate from the p-type Si thin film 30, and is made of a material substantially transparent to at least a visible light. In the present embodiment, the interlayer 62 is made of a material having the same refractive index as that of a material composing the oxide film 50. Alternatively, the interlayer 62 may be made of a material having a refractive index different from that of a material composing the oxide film 50. Then, the concave reflective layer 70 is formed on the surface of the interlayer 62, and is made of a metal material so as to have a concave surface 70a which has a shape corresponding to the convex surface 62a. The concave reflective layer 70 reflects a light incident on the concave surface 70a toward the p-type Si thin film 30 side, i.e., the photodiode portion 30a side.

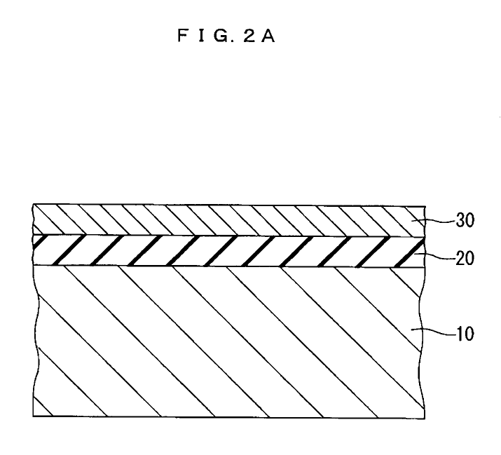

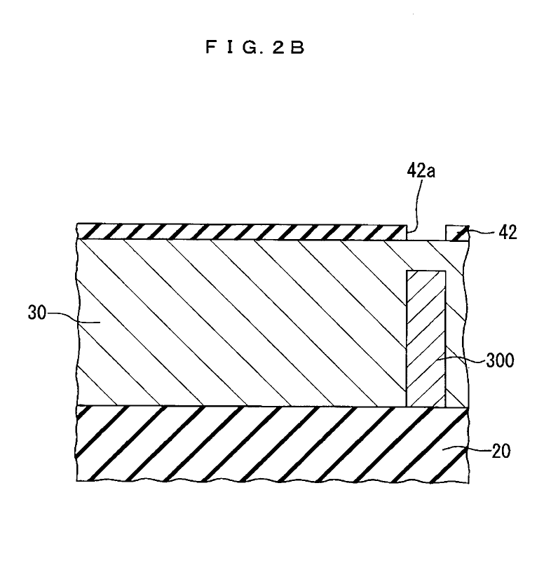

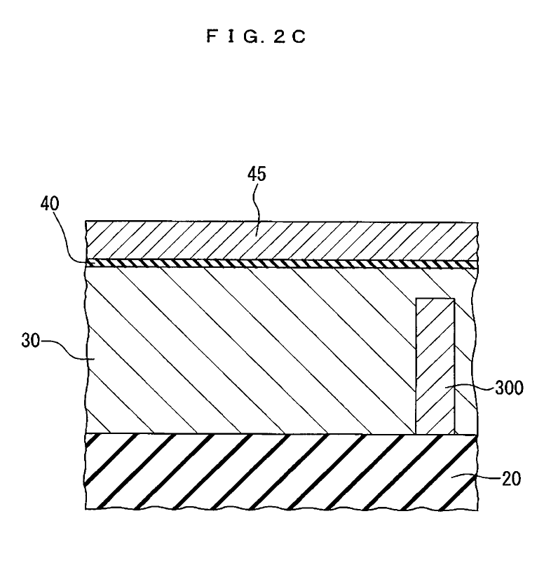

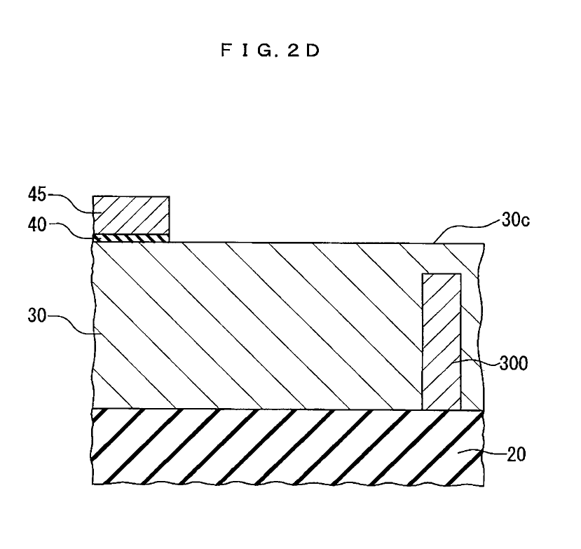

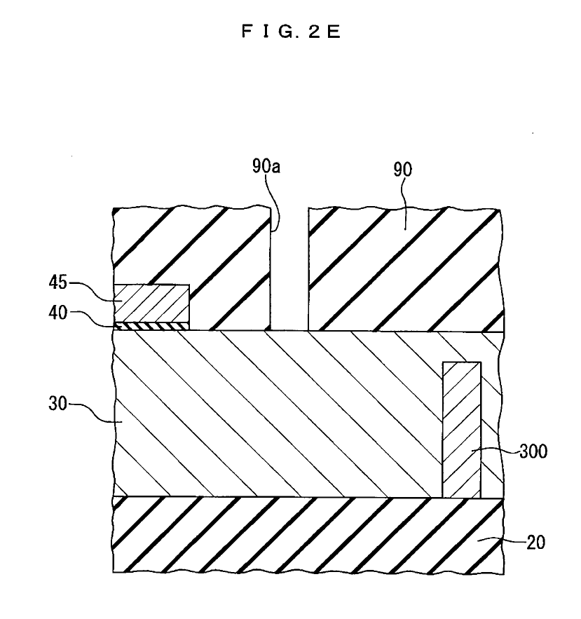

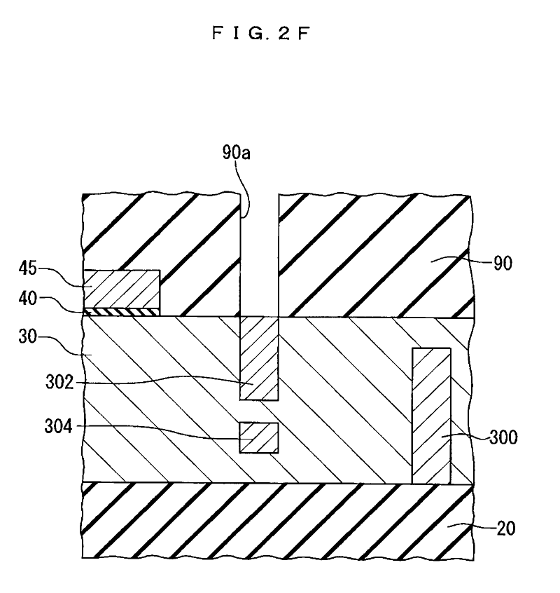

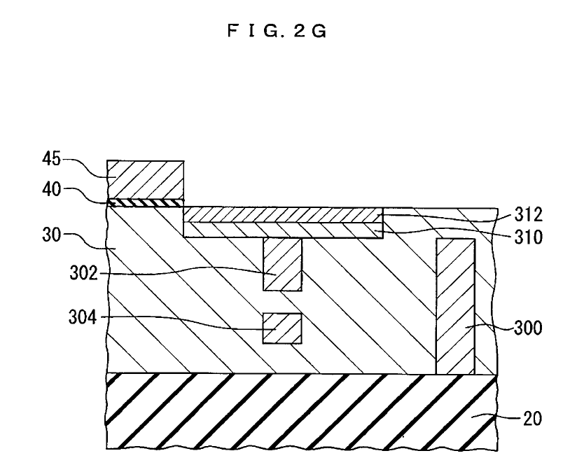

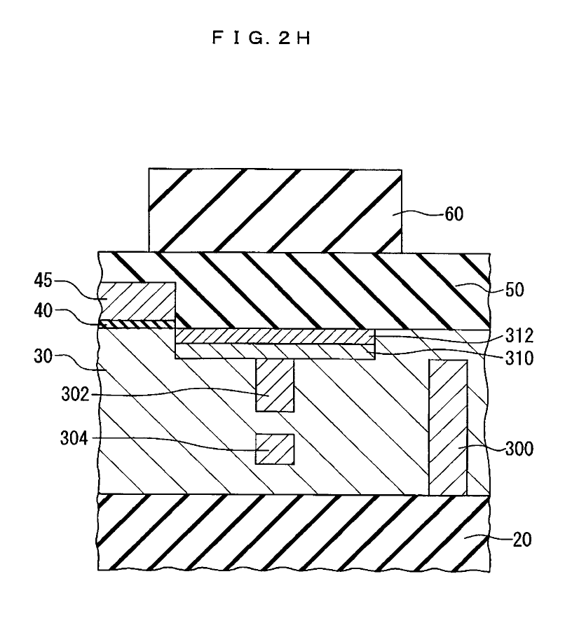

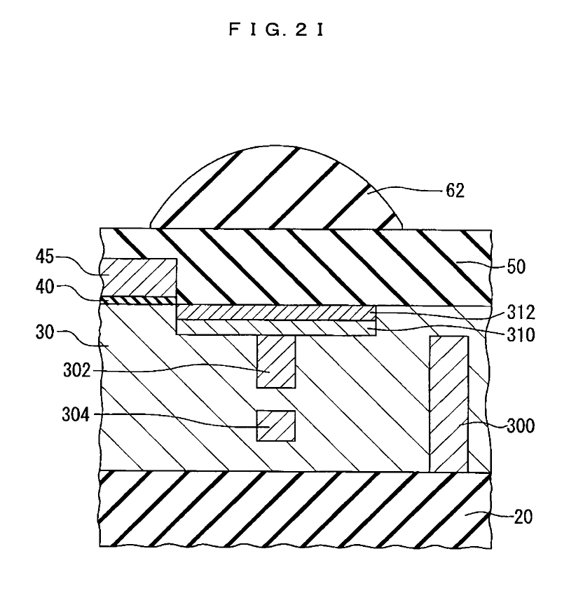

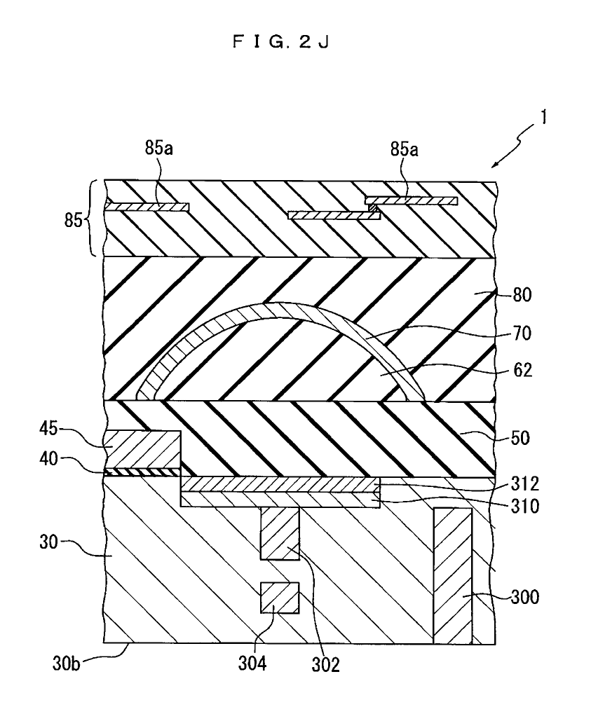

FIGS. 2A to 2J schematically show processes for fabricating the semiconductor device according to the first embodiment.

Firstly, as shown in FIG. 2A, a substrate which has a supporting substrate 10, an oxide film 20 provided on the supporting substrate 10 and a p-type Si thin film 30 as a Si thin film provided on the oxide film 20 is prepared. The supporting substrate 10 is, e.g., silicon (Si). The oxide film 20 is, e.g., made of silicon dioxide (SiO₂) and has a function as an insulating film which is formed by oxidizing the supporting substrate 10 for only a predetermined thickness from one surface toward another surface. In addition, the p-type Si thin film 30 is, e.g., a p-type Si film which is provided on the oxide film 20 so as to expose a (100) plane on the surface and is doped with a p-type impurity at a predetermined impurity concentration.

In the present embodiment, as an example, a Silicon on Insulator (SOI) wafer is prepared as the supporting substrate 10 having the oxide film 20 and the p-type Si thin film 30. Here, when a thickness of the p-type Si thin film 30 of the prepared SOI wafer is not sufficient for a desired thickness, for example, a Si layer can be further epitaxially grown on the prepared SOI wafer. Alternatively, it is possible to use a Separation by IMplanted OXygen (SIMOX) wafer instead of the SOI wafer.

Next, as shown in FIG. 2B, the n-type partition wall 300 is formed in a predetermined region in the p-type Si thin film 30. Concretely, firstly, a mask layer 42 made of an oxide material is formed on a surface of the p-type Si thin film 30. The mask layer 42 can be formed by, e.g., a Chemical Vapor Deposition (CVD) method. The mask layer 42 is, e.g., a SiO₂ film having a thickness of about 500 nm. Following this, an opening 42a is provided in the mask layer 42 using a photolithography method and an etching method.

Next, an n-type impurity material, e.g., phosphorus (P), is implanted into the p-type Si thin film 30 via the mask layer 42 by an ion implantation procedure while changing accelerating voltage in multiple steps. As a result, the n-type partition wall 300 composed of an n-type impurity layer having a predetermined impurity concentration is formed in the p-type Si thin film 30 below the opening 42a. After forming the n-type partition wall 300, the mask layer 42 is removed using hydrofluoric acid (HF) and rapid heating annealing is subsequently applied, thereby activating the n-type partition wall 300. The rapid heating annealing is performed by heating, e.g., in an inert atmosphere at a temperature of around 1000° C. for about several seconds.

Next, as shown in FIG. 2C, the gate oxide film 40 is formed by oxidizing the surface of the p-type Si thin film 30. The gate oxide film 40 is, e.g., about 10 nm thick. Next, the gate electrode 45 is formed on the gate oxide film 40. The gate electrode 45 can be made of, e.g., polysilicon and the thickness thereof is about 150 nm.

Following this, as shown in FIG. 2D, the gate electrode 45 and the gate oxide film 40 are formed in a desired shape using the photolithography method and the etching method. Through these processes, a surface 30c of the p-type Si thin film 30 is exposed except a portion where the gate oxide film 40 and the gate electrode 45 are formed.

Next, as shown in FIG. 2E, a photoresist 90 is formed. Concretely, a mask pattern composed of the photoresist 90 having an opening 90a is formed in a predetermined region between the gate oxide film 40 and the n-type partition wall 300 using the photolithography method. The surface of the p-type Si thin film 30 is exposed at a bottom portion of the opening 90a.

Then, an n-type impurity and a p-type impurity are sequentially implanted into the p-type Si thin film 30 by the ion implantation procedure using the photoresist 90 having the opening 90a as a mask. Concretely, firstly, the n⁺ region 302 having a predetermined impurity concentration is formed by implanting an n-type impurity into the p-type Si thin film 30 immediately under the opening 90a. Next, the p⁺ region 304 having a predetermined impurity concentration is formed by implanting a p-type impurity in the same way. The formed n⁺ region 302 and the p⁺ region 304 are in a substantially columnar shape when viewed in cross-section.

In the present embodiment, the p⁺ region 304 is formed by implanting, e.g., boron (B) by the ion implantation procedure. Meanwhile, the n⁺ region 302 is formed by implanting, e.g., P by the ion implantation procedure while changing accelerating voltage in multiple steps. In addition, the p⁺ region 304 is formed at a position deeper than the n⁺ region 302 from the surface of the p-type Si thin film 30. Here, the depth from the surface of the p-type Si thin film 30 where the p⁺ region 304 and the n⁺ region 302 are formed is set to a depth such that a center of curvature of the below-described concave reflective layer 70 is located between the p⁺ region 304 and the n⁺ region 302. Note that, the depths of the p⁺ region 304 and the n⁺ region 302 from the surface of the p-type Si thin film 30 can be set to a desired depth by adjusting accelerating voltage, etc., of an ion implantation condition in case of implanting an ion.

Next, the photoresist 90 is removed. Then, as shown in FIG. 2G, an n-type impurity is ion-implanted into the surface of the gate electrode 45 and the whole surface of the p-type Si thin film 30. As a result, the n⁺ layer 310 is formed at a predetermined depth from the surface of the p-type Si thin film 30. Furthermore, the p⁺ layer 312 is formed on the n⁺ layer 310 using the photolithography method and the ion implantation procedure. Then, for example, rapid heating annealing is performed in an inert atmosphere at a temperature of around 1000° C. for about several seconds, thereby activating the impurity in the gate electrode 45 and in the n⁺ layer 310 and the p⁺ layer 312 which also have an electrode function for a readout transistor. Note that, the n⁺ region 302 and the p⁺ region 304 are also activated by the rapid heating annealing, and a depletion layer with a high internal electric field is generated between the n⁺ region 302 and the p⁺ region 304. Namely, since the n⁺ region 302 and the p⁺ region 304 each have a steep impurity concentration gradient, a pn junction is formed between the n⁺ region 302 and the p⁺ region 304, thereby generating the depletion layer with a high internal electric field.

Following this, as shown in FIG. 2H, an oxide film 50 and a BSG film 60 are formed. Concretely, firstly, an oxide film layer made of, e.g., silicon dioxide is deposited about 300 nm thick on the surfaces of the gate electrode 45 and the p-type Si thin film 30 using the CVD method. Then, the deposited oxide film layer is removed up to about 100 nm using a Chemical Mechanical Polishing (CMP) method, thereby forming the oxide film 50 having a planarized surface. In the polishing process by the CMP method, a polishing amount is set such that the oxide film 50 is formed thicker than the summed thickness of the gate oxide film 40 and the gate electrode 45.

Following this, a boron silicate glass (BSG) film 60 as a Si oxide film containing predetermined amount of boron (B) is deposited on the oxide film 50. The BSG film 60 as a film is, e.g., about 200 nm thick. Alternatively, it is possible to deposit a phosphorus silicate glass (PSG) film or a boron phosphorus silicate glass (BPSG) film, etc., on the oxide film 50 instead of depositing the BSG film 60. Next, the BSG film 60 excluding a portion covering the p⁺ layer 312 and the n⁺ layer 310 when viewed from the top is shaped using the photolithography method and the RIE method. As a result, the BSG film 60 which covers the p⁺ layer 312 and the n⁺ layer 310 when viewed from the top is formed.

Next, as shown in FIG. 2I, heat treatment is applied to the BSG film 60 in a predetermined atmosphere at a predetermined temperature for predetermined time, thereby forming the interlayer 62. The heat treatment is carried out, e.g., at a temperature of about the softening temperature of the BSG film 60 or at a temperature lower than the softening temperature (e.g., about 750° C.). When the heat treatment is applied, the BSG film 60 is deformed into a convex shape in a cross section due to surface tension, thereby shaped into the interlayer 62. Here, the convex shape of the interlayer 62 in a cross section is a shape which matches a shape of a portion of a parabola.

Next, the concave reflective layer 70 having a concave surface of which focal point is located between the n⁺ region 302 and the p⁺ region 304 is formed on the surface of the interlayer 62. The concave reflective layer 70 is made of a metal material having a high reflectance ratio (e.g., about 90%) with respect to a light in a visible light region. The concave reflective layer 70 is formed, e.g., about 150 nm thick by a sputtering method. Concretely, a metal layer having a predetermined thickness is formed on the surface of the interlayer 62 as well as the surface of the oxide film 50 by the sputtering method. Then, the concave reflective layer 70 is formed on the surface of the interlayer 62 using the photolithography method and the RIE method. Note that, the concave reflective layer 70 can be mainly made of, e.g., a metal material such as aluminum or silver, etc. Following this, after forming the concave reflective layer 70 on the surface of the interlayer 62, annealing treatment is applied to the concave reflective layer 70 at about 400° C. for 5 minutes. Note that, duration of the annealing treatment is set within a range in which the metal material composing the concave reflective layer 70 does not reach the photodiode portion 30a side by diffusing in the oxide film 50.

Subsequently, the interlayer insulating film 80 having a predetermined thickness is formed so as to cover the surface of the oxide film 50 as well as the surface of the concave reflective layer 70. The interlayer insulating film 80 can be made of, e.g., a silicon dioxide film. Next, after planarizing the surface of the interlayer insulating film 80 by the CVD method, a wiring layer 85 as a multilayer wiring is formed on the surface of the interlayer insulating film 80 as shown in FIG. 2J. The wiring layer 85 is formed having a predetermined wiring pattern composed of copper wirings 85a. Next, the supporting substrate 10 and the oxide film 20 are polished and removed, thereby forming the semiconductor device 1 according to the present embodiment.

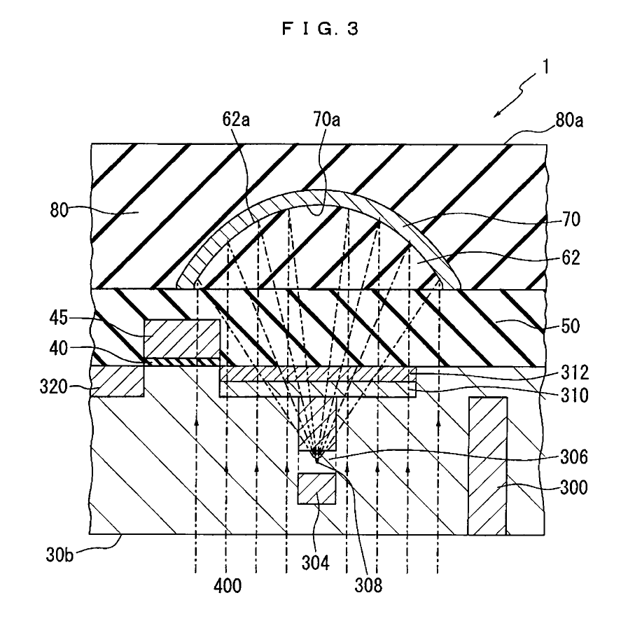

FIG. 3 schematically shows an operation of the semiconductor device according to the first embodiment.

As an example, FIG. 3 shows the case that the refractive index of a material composing the oxide film 50 is same as that of a material composing the interlayer 62. Note that, illustration of the wiring layer 85 is omitted in FIG. 3 for the convenience of explanation. Referring to FIG. 3, a light 400 incident on the light incident plane 30b of the semiconductor device 1 propagates in the p-type Si thin film 30. In the present embodiment, the p-type Si thin film 30 is about 1.5 μm thick, and a portion of the light 400, especially the light 400 having a wavelength in a red region, is easily transmitted through the p-type Si thin film 30. The light 400 transmitted through the p-type Si thin film 30 is reflected by the concave reflective layer 70.

Here, since the concave reflective layer 70 according to the present embodiment is formed such that the a center of curvature 308 is present between the n⁺ region 302 and the p⁺ region 304, the light 400 reflected by the concave reflective layer 70 is focused on a depletion layer 306 which is present between the n⁺ region 302 and the p⁺ region 304. Note that, when a curved line of the concave surface portion of the concave reflective layer 70 does not have a perfect parabolic shape, even though the light 400 reflected by the concave reflective layer 70 does not focus on one point in the depletion layer 306, the light 400 having a predetermined extent is focused in the depletion layer 306.

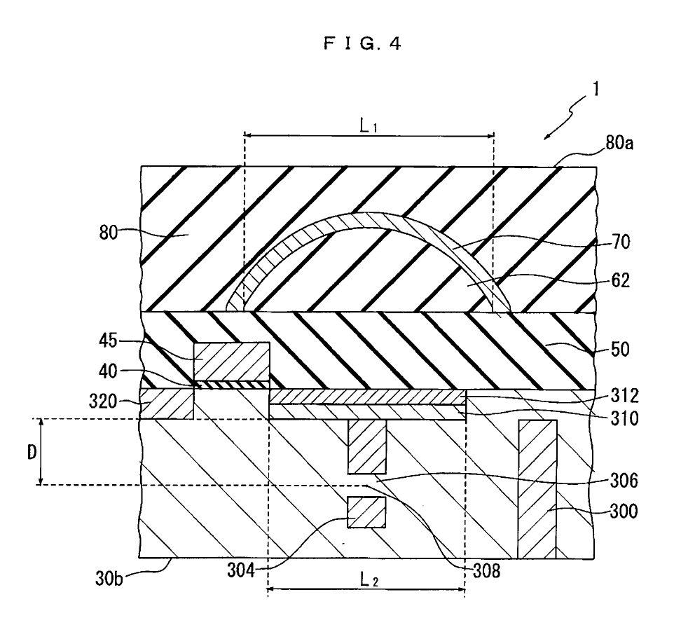

FIG. 4 schematically shows a position of a center of curvature of the semiconductor device according to the first embodiment.

In the present embodiment, a width L1 of the interlayer 62 when viewed from the top is set to a width greater than a width L2 of the n⁺ layer 310 and the p⁺ layer 312. Furthermore, a concave shape of the concave reflective layer 70 is set so that a center of curvature 308 of the concave reflective layer 70 is located between the n⁺ region 302 and the p⁺ region 304. In this case, the center of curvature 308 of the concave reflective layer 70 is located at a predetermined depth D from an interface between the n⁺ layer 310 and the p-type Si thin film 30. The depth D can be brought closer to the n⁺ layer 310 side in order to improve photosensitivity of the semiconductor device 1. Namely, it is possible to bring the center of curvature 308 closer to the n⁺ layer 310 side. Note that, by changing a shape of the convex surface 62a of the interlayer 62 in accordance with the change of the position of the depth D, it is possible to change the shape of the concave surface 70a of the concave reflective layer 70.

Although the p-type Si thin film 30 is used in the present embodiment, it is possible to use an n-type Si thin film. In this case, a conductivity type of each component of the semiconductor device 1 is reversed from the conductivity type in the present embodiment. For example, the n-type partition wall 300 is configured as p-type. In addition, the n⁺ region 302 and the n⁺ layer 310 are configured as p-type, and the p⁺ region 304 and the p⁺ layer 312 are configured as n-type.

The semiconductor device 1 according to the present embodiment is provided with the concave reflective layer 70 on the opposite side of the light incident plane 30b of the p-type Si thin film 30 including the photodiode portion 30a. A portion of the light incident on the light incident plane 30b is reflected by the concave reflective layer 70. Then, since a passage distance in the photodiode portion 30a is increased in accordance with the increase of a path of the reflected light by the reflection, photoelectric conversion efficiency in the photodiode portion 30a is improved. As a result, according to the present embodiment, it is possible to provide the semiconductor device 1 with improved photosensitivity. In addition, since the light incident on the light incident plane 30b is reflected by the concave reflective layer 70 toward between the n⁺ region 302 and the p⁺ region 304 and it is thereby possible to suppress the propagation of the light upward of the concave reflective layer 70, it is possible to freely design a layout of the wiring 85a in the wiring layer 85.

In addition, in the semiconductor device 1 according to the present embodiment, a light in the red region transmitted through the p-type Si thin film 30 among the light incident on the light incident plane 30b can be reflected on the photodiode portion 30a side by the concave reflective layer 70. As a result, since it is possible to improve the photoelectric conversion efficiency of a red light without thickening the p-type Si thin film 30, the thickness of the p-type Si thin film 30 can be thinned compared with the semiconductor device in which the concave reflective layer 70 is not provided, and it is thereby possible to reduce the fabrication cost of the semiconductor device 1. Furthermore, since the thickness of the p-type Si thin film 30 is still thin, formation of the n-type partition wall 300 for isolating the plural photodiode portions 30a is facilitated, and it is thereby possible to provide the semiconductor device 1 as a CMOS sensor with greatly improved photosensitivity ata low cost.

In addition, since the semiconductor device 1 according to the present embodiment is provided with the oxide film 50 between the concave reflective layer 70 and the photodiode portion 30a, the metal material composing the concave reflective layer 70 diffuses into the photodiode portion 30a side, and it is thereby possible to suppress deterioration of characteristics of the semiconductor device 1.

In addition, in the semiconductor device 1 according to the present embodiment, it is possible to focus the light reflected by the concave reflective layer 70 in the depletion layer 306. Here, since the depletion layer 306 is formed in a region sandwiched by the n⁺ region 302 with a high impurity concentration as well as with a steep impurity concentration profile and the p⁺ region 304 with a high impurity concentration as well as with a steep impurity concentration profile, the electric field strength in the depletion layer 306 is high and the light entered the depletion layer 306 is immediately converted into carrier at high efficiency. As a result, according to the semiconductor device 1 of the present embodiment, it is possible to perform very high photoelectric conversion efficiency.

In addition, since the n⁺ region 302 and the p⁺ region 304 are each separated from the gate electrode 45 as a readout transistor, it is possible to suppress deterioration of characteristics of the readout transistor such as generation of punchthrough, etc. Therefore, the semiconductor device 1 according to the present embodiment can be provided as a highly sensitive CMOS sensor.

### Second Embodiment

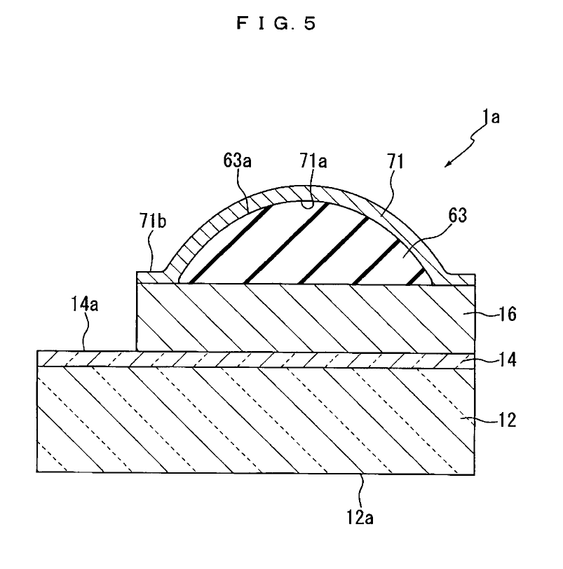

FIG. 5 is a schematic cross sectional view showing a semiconductor device according to a second embodiment.

A semiconductor device 1a according to the second embodiment includes a transparent substrate 12 having a light incident plane 12a, a transparent electrode 14 provided on the transparent substrate 12, an organic semiconductor layer 16 provided on a portion of the transparent electrode 14, an interlayer 63 provided on a portion of the organic semiconductor layer 16, and a concave reflective layer 71 provided in contact with the surface of the interlayer 63 and a surface of a portion of the organic semiconductor layer 16.

The transparent substrate 12 is transparent to a visible light, and is made of a material having flexibility. For example, the transparent substrate 12 can be formed of a transparent film made of an organic polymeric material. Meanwhile, the transparent electrode 14 can be made of a conductive inorganic material such as Indium Tin Oxide (ITO), etc. A surface 14a as a portion of the transparent electrode 14 is an externally exposed, and the power is supplied to the organic semiconductor layer 16 from this region.

The organic semiconductor layer 16 is formed containing an organic material having a function of accepting an electron (hereinafter referred to as “electron-accepting organic material”) and/or an organic material having a function of donating an electron (hereinafter referred to as “electron-donating organic material”), and performs a function as a photodiode for photoelectric conversion. The organic semiconductor layer 16 can be formed including a layer made of the electron-accepting organic material, a layer made of the electron-donating organic material, or a laminated layer of the layer made of the electron-accepting organic material and the layer made of the electron-donating organic material. Alternatively, it is possible to form the organic semiconductor layer 16 including a layer in which the electron-accepting organic material or electron-donating organic material is added to an organic polymeric material such as acrylic resin, epoxy resin or polyamide resin, etc., or, the copolymer of these organic polymeric materials.

Alternatively, the organic semiconductor layer 16 can be formed containing an organic material absorbing light in a predetermined visible light region. For example, the organic semiconductor layer 16 can be formed containing Coumarin 6 which is an organic material absorbing light in a blue region, Rhodamine 6G which is an organic material absorbing light in a green region, or zinc phthalocyanine which is an organic material absorbing light in a red region. In this case, the organic semiconductor layer 16 can be formed including a laminated structure in which, for example, a first organic semiconductor layer containing Coumarin 6, a second organic semiconductor layer containing Rhodamine 6G and a third organic semiconductor layer containing zinc phthalocyanine are laminated.

The interlayer 63 can be made of, e.g., an organic polymeric material such as epoxy resin, etc. For example, it is possible to form the interlayer 63 by potting the organic polymeric material such as epoxy resin, etc., on a portion of the organic semiconductor layer 16. As a result, it is possible to form the interlayer 63 having a convex surface 63a. Meanwhile, the concave reflective layer 71 is formed having a concave surface 71a which corresponds to the convex surface 63a. A material composing the concave reflective layer 71 is same as the first embodiment. In addition, it is possible to contact a portion of the concave reflective layer 71 with the organic semiconductor layer 16, and in this case, the concave reflective layer 71 also has a function as an electrode for supplying power to the organic semiconductor layer 16. For example, the power is externally supplied to a surface 71b of the concave reflective layer 71.

Since it is possible to form the semiconductor device 1a of the second embodiment mainly from the polymeric material and the organic semiconductor, bendability and flexibility are exerted. Therefore, according to the present embodiment, it is possible to provide the semiconductor device 1a as a photosensor which has high photosensitivity due to the presence of the concave reflective layer 71 and in which the semiconductor device 1a itself can be freely bent. As a result, according to the present embodiment, it is possible to provide the semiconductor device 1a which can be attached on cloths, etc.

### Third Embodiment

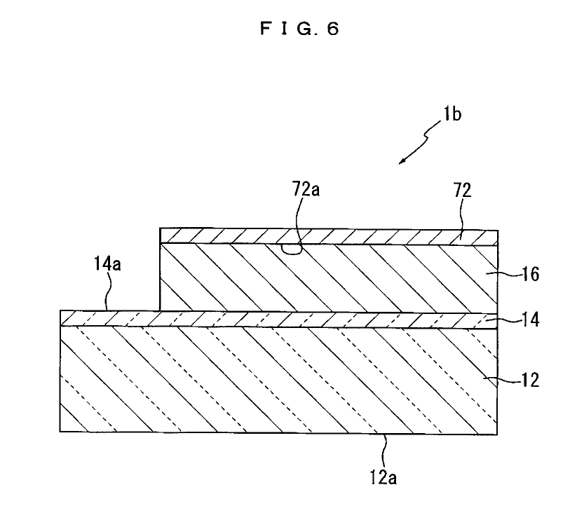

FIG. 6 is a schematic cross sectional view showing a semiconductor device according to a third embodiment.

A semiconductor device 1b according to the present embodiment has the substantially same configuration as the semiconductor device 1a according to the second embodiment, except that the interlayer 63 is not provided and the concave reflective layer 71 does not exist. Therefore, the detailed explanation will be omitted except for the difference.

The semiconductor device 1b includes a transparent substrate 12, a transparent electrode 14 provided on the transparent substrate 12, an organic semiconductor layer 16 provided on a portion of the transparent electrode 14, and a reflecting electrode 72 as a reflective layer provided on the organic semiconductor layer 16. At a surface 72a, the reflecting electrode 72 reflects a portion of the light entered from the light incident plane 12a toward the organic semiconductor layer 16 side. In addition, the reflecting electrode 72 has a function as an electrode for supplying the power to the organic semiconductor layer 16.

Although the embodiments have been described, the above-mentioned embodiments do not limit the invention according to the scope of claims. In addition, all combinations of characteristics explained in the embodiments are not necessarily essential for solving the problem of the present invention.

What is claimed is:

1. A semiconductor device, comprising:
a semiconductor thin film comprising a light incident plane on which a light is incident and a photodiode portion;
an interlayer provided above a surface of the semiconductor thin film on an opposite side of the light incident plane, and having a convex surface; and
a concave reflective layer provided on the surface of the convex surface, and having a concave surface for reflecting the light toward the photodiode portion.

2. The semiconductor device according to claim 1, wherein the photodiode portion comprises a first region of a first conductivity type and a second region of a second conductivity type different from the first conductivity type; and
the interlayer has the convex surface having a shape such that a center of curvature of the concave surface is located in a depletion layer between the first and second regions.

3. The semiconductor device according to claim 2, wherein the first and second regions are formed in a portion of the semiconductor thin film, and have an impurity concentration higher than that of the semiconductor thin film excluding the first and second regions.

4. The semiconductor device according to claim 2, wherein the second region is provided between the light incident plane and the first region.

5. The semiconductor device according to claim 2, wherein the semiconductor thin film comprises a first layer of a first conductivity type and a second layer of a second conductivity type different from the first conductivity type; and
the center of curvature is located between the first and second layers and the second region.

6. The semiconductor device according to claim 1, further comprising:
an oxide film provided between the semiconductor thin film and the interlayer; and
a wiring layer provided on the interlayer,
wherein the concave reflective layer is provided between the oxide film and the wiring layer.

7. The semiconductor device according to claim 6, wherein the semiconductor device is a backside irradiation type semiconductor device in which a light incident on the light incident plane located on an opposite side of the wiring layer is reflected by the concave reflective layer.

8. The semiconductor device according to claim 6, wherein the interlayer and the oxide film are made of materials having the same refractive index.

9. The semiconductor device according to claim 1, wherein the concave reflective layer is made of a metal material.

10. The semiconductor device according to claim 1, wherein the semiconductor thin film is a p-type or n-type Si thin film.

11. A semiconductor device, comprising:
a transparent substrate having flexibility;
a transparent electrode provided on the transparent substrate;
an organic semiconductor layer provided on a portion of the transparent electrode on an opposite side of a surface thereof in contact with the transparent substrate;
an interlayer provided above a surface of the organic semiconductor layer on an opposite side of a surface thereof in contact with the transparent electrode, and having a convex surface; and
a concave reflective layer provided on the surface of the convex surface, and having a concave surface for reflecting an incident light toward the organic semiconductor layer.

12. The semiconductor device according to claim 11, wherein the organic semiconductor layer is formed containing one of, or both of an electron-accepting organic material and an electron-donating organic material.

13. The semiconductor device according to claim 11, wherein the organic semiconductor layer is formed containing at least one organic material selected from Coumarin 6, Rhodamine 6G and zinc phthalocyanine.

14. The semiconductor device according to claim 11, wherein the concave reflective layer is made of a metal material, and is an electrode for supplying power to the organic semiconductor layer.

15. A semiconductor device, comprising:
a transparent substrate having flexibility, and being transparent to a visible light;
a transparent electrode provided on the transparent substrate;
an organic semiconductor layer provided on a portion of the transparent electrode on an opposite side of a surface thereof in contact with the transparent substrate; and
an reflective layer provided above a surface of the organic semiconductor layer on an opposite side of a surface thereof in contact with the transparent electrode.

16. The semiconductor device according to claim 15, wherein the reflective layer is an electrode for supplying power to the organic semiconductor layer.

17. A method of fabricating a semiconductor device, comprising:
forming a film on a semiconductor thin film having an oxide film formed on a surface thereof, the semiconductor thin film comprising a light incident plane on which a light is incident and a photodiode portion;
processing the film into an interlayer having a convex shape by applying heat treatment to the film; and
forming a concave reflective layer on a surface of the interlayer.

18. The method of fabricating a semiconductor device according to claim 17, wherein the photodiode portion is fabricated through a process of preparing a substrate comprising a supporting substrate, an oxide film on the supporting substrate and a Si thin film on the oxide film, and a process of forming a first region of a first conductivity type and a second region of a second conductivity type different from the first conductivity type in the Si thin film.

19. The method of fabricating a semiconductor device according to claim 17, wherein the heat treatment in the process of forming the interlayer is carried out at a softening temperature of a material for forming the film or at a temperature lower than the softening temperature.

20. The method of fabricating a semiconductor device according to claim 18, wherein the concave reflective layer is formed having a concave surface of which focal point is located between the first and second regions.
